(19) United States
(12) Patent Application Publication
(10) Pub. No.: US 2024/0315117 A1
(43) Pub. Date: Sep. 19, 2024

(54) Display Panel

(71) Applicant: Najing Technology Corporation Limited, Zhejiang (CN)

(72) Inventors: Xinyan GU, Hangzhou, Zhejiang (CN); Wenling AI, Hangzhou, Zhejiang (CN)

(21) Appl. No.: 18/271,856

(22) PCT Filed: Jan. 10, 2022
(86) PCT No.: PCT/CN2022/070887

§ 371 Date: Jul. 12, 2023

(30) Foreign Application Priority Data
Jan. 12, 2021 (CN) 202110037435.3

(51) Int. Cl. H10K 59/80; H10K 102/00

(52) U.S. Cl. CPC H10K 59/879; H10K 2102/331

(57) ABSTRACT

A display panel, including an anti-reflection film and a light-emitting element, the light-emitting element includes a substrate and a plurality of mutually isolated sub-pixels disposed on a surface of the substrate; each of the sub-pixels includes a bottom electrode, a functional layer, and a top electrode which are sequentially stacked; at least a part of the sub-pixels further include a light extraction layer; the light extraction layer is disposed on a surface of the top electrode away from the functional layer; and nanoparticles are disposed in the light extraction layer; and a diameter of the nanoparticles does not exceed 40 nm. The display panel has high contrast, while achieving the effect of improving its lifetime.

### CROSS-REFERENCE TO RELATED APPLICATIONS

This application is a national phase entry under 35 U.S.C. § 371 of International Patent Application PCT/CN2022/070887, filed Jan. 10, 2022, designating the United States of America and published as International Patent Publication WO 2022/152062 A1 on Jul. 21, 2022, which claims the benefit under Article 8 of the Patent Cooperation Treaty to Chinese Patent Application Serial No. 202110037435.3, filed on Jan. 12, 2021, the disclosure of which is hereby incorporated herein in its entirety by this reference.

### TECHNICAL FIELD

The present disclosure relates to the field of photoelectric technology, and in particular relates to a display panel.

### BACKGROUND

OLED (Organic Light-Emitting Diode) display devices have features such as fast response and high contrast, and thus occupy increasing shares in the display market. However, there is still no good solution for problems such as burn-in and short life of the OLED at present. In addition, the electrodes of such electroluminescent device (generally, one side of the electrode is made of metal) has strong reflectivity, which will cause ambient light to be reflected by the panel and emitted, and mixed with the self-luminous light of the panel, resulting in a decrease in the contrast of the display panel. In order to avoid the above problem, a circular polarizer becomes an indispensable component of the display panel, but its introduction may cause about half of the light loss. Meanwhile, in order to improve the lifetime of the display panel, a top-emission panel with a high aperture ratio has become a research focus in the art. Arranging a capping layer at the top of the top-emission display panel becomes a conventional means for improving the external quantum efficiency, but the improvement ratio thereof is still very limited.

On the other hand, the lens-type and scattering-type light extraction structures significantly improve the light extraction efficiency of the display panel. However, when they are combined with the circular polarizer, the effect of the circular polarizer for suppressing ambient light reflection can be destroyed. That is, when the display panel is not lighted up, observing the display panel through a circular polarizer, it will no longer show the “dark field” effect of all-black (all-black effect refers to that the ambient light transmits into the panel but not comes out), but present a certain degree of gray. The destruction of the “dark field” effect greatly affect the contrast of the display panel.

### SUMMARY

An object of the present disclosure is to provide a display panel, the display panel includes an anti-reflection film and a light-emitting element, wherein the light-emitting element includes a substrate and a plurality of mutually isolated sub-pixels disposed on a surface of the substrate, each of the sub-pixels includes a bottom electrode, a functional layer and a top electrode which are sequentially stacked, and at least part of the sub-pixels further include a light extraction layer, the light extraction layer is disposed on a surface of the top electrode away from the functional layer, and nanoparticles are disposed in the light extraction layer, a diameter of the nanoparticles does not exceed 40 nm.

Optionally, a mass fraction of the nanoparticles in the light extraction layer is ≥70 wt %.

Optionally, a mass fraction of the nanoparticles in the light extraction layer is ≥50 wt %, and the light extraction layer includes a polymer matrix having a refractive index of greater than 1.65.

Optionally, the diameter of nanoparticles is 5 to 30 nm.

Optionally, the nanoparticles have a refractive index of ≥1.8.

Optionally, the surface of the nanoparticles is a curved surface.

Optionally, the nanoparticles are selected from any one or a combination of zinc oxide, titanium oxide, tantalum pentoxide, yttrium oxide, zirconium oxide, aluminium oxide, niobium oxide, tungsten oxide, antimony oxide, vanadium oxide and molybdenum oxide.

Optionally, the light extraction layer has a thickness of 0.5 to 10 μm.

Optionally, the light extraction layer has a flatness Ra of ≤20 nm.

Optionally, under theirradiation of light with a wavelength of 550 nm, a transmittance of the light extraction layer is no more than 80%.

Optionally, the light extraction layer includes at least one type of auxiliary material, and under the irradiation of visible light, a light transmittance of the auxiliary material is not less than 80%.

Optionally, the total mass fraction of the auxiliary material in the light extraction layer is not more than 30 wt %, and the refractive index of each of the auxiliary materials is not less than 1.4.

Optionally, the auxiliary material includes an interface modifier, the interface modifier is coordinated to the surface of the nanoparticles.

Optionally, the light-emitting element further includes an interface layer, which is disposed on a surface of the light extraction layer away from the substrate, a transmittance of the interface layer is not less than 80% under the irradiation of light with a wavelength of 550 nm, and the refractive index of the interface layer is ≤1.8.

Optionally, a thickness of the interface layer is 0.1 to 5 μm.

Optionally, the sub-pixel with the highest initial external quantum efficiency is defined as a first sub-pixel, the sub-pixel with the lowest initial external quantum efficiency is defined as a third sub-pixel, and the sub-pixel with an initial external quantum efficiency between the first sub-pixel and the third sub-pixel is defined as a second sub-pixel; the improvement ratio of the external quantum efficiency of the light extraction layer of the first sub-pixel is X₁, the improvement ratio of the external quantum efficiency of the light extraction layer of the second sub-pixel is X₂, and the improvement ratio of the external quantum efficiency of the light extraction layer of the third sub-pixel is X₃. The X₁, the X₂ and the X₃ are not equal, Xₙ=(Q₂−Q₁)/Q₁, where n is a natural number selected from 1 to 3, Q₁ is the original external quantum efficiency corresponding to the sub-pixel, Q₂ is the actual external quantum efficiency corresponding to the sub-pixel; the Xₙ is ≥0.5.

Optionally, in a non-lighted state of the display panel, the display panel presents an all-black effect.

Applying the technical solution of the present disclosure, i.e. disposing a light extraction layer above the top electrode by using nanometer-sized particles as light extraction particles, significantly improves the external quantum efficiency of the display panel without affecting the dark field effect of the anti-reflection film; therefore, it ensures that the display panel has a high contrast, while achieving the effect of improving its lifetime.

### BRIEF DESCRIPTION OF THE DRAWINGS

The accompany drawings, which form a part of the present disclosure, are used to provide further understanding of the present disclosure. The schematic embodiments of the present disclosure and the description thereof are used to explain the present disclosure, and do not form improper limits to the present disclosure. In the drawings:

FIG. 1 is a schematic diagram showing a cross-sectional structure of a display panel according to an embodiment of the present disclosure;

FIG. 2 is a schematic diagram showing a cross-sectional structure of a display panel according to an embodiment of the present disclosure;

FIG. 3 is a schematic diagram showing a cross-sectional structure of a display panel according to an embodiment of the present disclosure;

FIG. 4 is a schematic diagram showing a cross-sectional structure of a display panel according to an embodiment of the present disclosure;

FIG. 5 is a photograph of the light-emitting elements with circular polarizers of Comparative Example 2 and Examples 1, 2, 6, 7, and 8 of the present disclosure in a non-lighted state, the first row corresponds to Comparative Example 2, Example 1, and Example 2 in sequence from left to right, and the second row corresponds to Example 6, Example 7, and Example 8 in sequence from left to right (the circles in the photograph are air bubbles caused by bonding films).

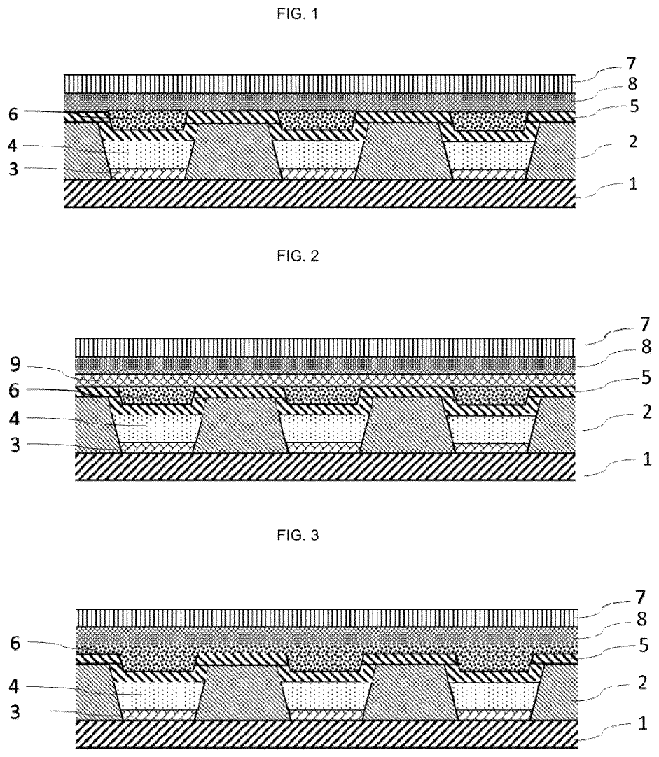

The figures include the following reference numerals:
1. Substrate. 2. Pixel isolation structure. 3. Bottom electrode. 4. Functional layer. 5. Top electrode. 6. Light extraction layer. 7. Anti-reflection film. 8. Encapsulation layer. 9. Interface layer.

### DETAILED DESCRIPTION

It should be noted that the following detailed description is illustrative and is intended to provide further explanation of the present disclosure. Unless otherwise indicated, all technical and scientific terms used herein have the same meaning as commonly understood by one of ordinary skill in the art to which this disclosure belongs.

It should be noted that the terms “first” and “second”, etc. in the specification and claims of the present disclosure are used for distinguishing similar objects, but are not necessarily used for describing a specific sequence or order. It should be understood that the data termed in such a way may be interchangeable in proper circumstances so that the examples of the present disclosure described herein. In addition, the terms “include” and “contain”, and any variations thereof, are intended to cover a non-exclusive inclusion, for example, a process, method, system, product, or device that includes a series of steps or units is not necessarily limited to those steps or units that are expressly listed, but may include other steps or units that are not expressly listed or inherent to such process, method, product, or device. It should be understood that in describing various layer structures in the present disclosure, the description of “on” or “above” is merely used to indicate relative positions between layers, and may include cases of direct contact and indirect contact (i.e., the presence of an intermediate layer).

The lens-type and scattering-type light extraction structures in the prior art significantly improve the light extraction efficiency of the display panel, but when they are used in combination with the circular polarizer, the effect of the circular polarizer for suppressing ambient light reflection will be destroyed. The inventors have found that the main reason for the above problem is that only the circular polarizer combined with the specular reflection can achieve an all-black effect, and the light extraction structure or other film layers and components located on the side of the circular polarizer close to the substrate may destroy the specular reflection, so that a part of light cannot be absorbed by the circular polarizer, and thus the part of light may be reflected out and enters into the human eyes.

The present disclosure provides a display panel, including an anti-reflection film 7 and a light-emitting element. The light-emitting element includes a substrate 1 and a plurality of mutually isolated sub-pixels disposed on a surface of the substrate 1, each of the sub-pixel includes a bottom electrode 3, a functional layer 4 and a top electrode 5 which are sequentially stacked, and at least part of the sub-pixels further include a light extraction layer 6, the light extraction layer 6 is disposed on a surface of the top electrode 5 away from the functional layer 4, and nanoparticles are disposed in the light extraction layer 6, and a diameter of nanoparticle does not exceed 40 nm.

According to the technical solution of the present disclosure, the light extraction layer is disposed above the top electrode by using nanometer-sized particles as light extraction particles, when the ambient light irradiates on the display panel, about half of the ambient light is firstly absorbed by the anti-reflection film (for example, the circular polarizer), when the remaining half of the light exits the anti-reflection film and reaches the interface of the light extraction layer, most of the light is reflected by the reflection interface and re-emitted to the anti-reflection film, the phase of the reflected light just conforms to the absorption direction of the anti-reflection film, so that the ambient light is almost completely absorbed by the anti-reflection film, thus, the adverse effect of ambient light on the contrast of the display panel is reduced. Thus, the external quantum efficiency of the display panel is greatly improved, and the dark field effect of the anti-reflection film is not affected. It ensures that the display panel has a high contrast, while improving its lifetime.

It should be noted that the nanoparticles play the role of light extraction particles in the light extraction layer, and the nanoparticles do not have the function of light conversion, and the light extraction layer does not include micron-sized light extraction particles. The diameter of the nanoparticles refers to the average diameter of the nanoparticles. The anti-reflection film is optically connected to the light-emitting element, and the anti-reflection film may be located right above the light-emitting element.

In some embodiments, the variation in diameter of the nanoparticles in the light extraction layer is within plus or minus 25%, preferably within plus or minus 10%. On the premise that the diameter does not exceed 40 nm, the nanoparticles with good diameter uniformity are beneficial for obtaining a light extraction layer with good flatness.

“At least part of the sub-pixels further include the light extraction layer 6” means that at least a part of the top electrode 5 is covered by the light extraction layer 6.

In some embodiments, the light extraction layer 6 is a continuous layer, and in other embodiments, the light extraction layer 6 includes a plurality of separated layers disposed in an array.

In some embodiments, the light-emitting element further includes a plurality of pixel isolation structures 2 (also referred to as banks) disposed on the substrate 1, and a plurality of mutually isolated light-emitting regions defined by the pixel isolation structures 2, wherein the plurality of sub-pixels are disposed in the plurality of light-emitting regions in one-to-one correspondence.

In some embodiments, the functional layer 4 of each sub-pixel may include an electron injection layer, an electron transport layer, a light-emitting layer, a hole transport layer and a hole injection layer which are sequentially stacked.

In other embodiments, the light-emitting element and the anti-reflection film 7 are disposed in parallel, and other layers (such as the encapsulation layer 8) may be disposed between the light-emitting element and the anti-reflection film 7.

In other embodiments, other structures are further disposed outside the anti-reflection film 7, thereby forming a complete display panel.

In some embodiments, the display panel includes an encapsulation layer 8 disposed on a surface of the light extraction layer 6 away from the substrate 1. On the one hand, the encapsulation layer can improve the water and oxygen resistance performance of the display panel; on the other hand, when the encapsulation layer is a thin-film encapsulation layer, after the stacked layers of the thin-film encapsulation is disposed on the surface of the light extraction layer, then the light extraction layer can be planarized.

In some embodiments, the display panel further includes a layer located between the encapsulation layer 8 and the anti-reflection film 7.

In some embodiments, the light extraction layer 6 may be disposed on the surface of the top electrode 5 as a whole, as shown in FIG. 3. In this way, it is favorable to prepare the light-emitting element through coating process, and the manufacturing method is simple.

In some embodiments, the anti-reflection film 7 in the display panel is a circular polarizer. The anti-reflection film may also be selected from other replacements in the technical field that have the same or similar function as the circular polarizer. The anti-reflection film plays a role in preventing ambient light from being reflected and emits out of the panel, thus preventing reducing the contrast of the display panel after the ambient light is mixed with the self-luminous light of the panel.

In some embodiments, the nanoparticles have a diameter greater than 1 nm but no greater than 3 nm, or no greater than 5 nm, or no greater than 7 nm, or no greater than 9 nm, or no greater than 13 nm, or no greater than 16 nm, or no greater than 19 nm, or no greater than 21 nm, or no greater than 24 nm, or no greater than 27 nm, or no greater than 29 nm, or no greater than 33 nm, or no greater than 36 nm, or no greater than 39 nm. In some embodiments, the nanoparticles have a diameter of 5 to 30 nm. In some embodiments, the nanoparticles have a diameter of 10˜25 nm. The above diameter can ensure that the nanoparticles have a higher refractive index and light extraction effect.

In some embodiments, a mass fraction of nanoparticles in the light extraction layer 6 is ≥70 wt %, or ≥75 wt %, or ≥80 wt %, or ≥85 wt %, or ≥90 wt %, or ≥95 wt %. The nanoparticles with the above mass fraction can ensure that the total refractive index of the light extraction layer is relatively high, and the total refractive index=Σ (the volume proportion of a single component)*(the value of the refractive index of the single component).

In some embodiments, a mass fraction of the nanoparticles included in the light extraction layer 6 is ≥50 wt %, or ≥55 wt %, or ≥60 wt %, or ≥65 wt %, and the light extraction layer includes a polymer matrix having a refractive index greater than 1.65.

In some embodiments, the nanoparticles have a refractive index of ≥1.8, or ≥2.

In some embodiments, the surface of the nanoparticle is a curved surface, preferably the shape of the nanoparticle is spherical, spheroidal, elliptical or ellipsoidal. Such nanoparticles may have better stacking flatness.

In some embodiments, the nanoparticles may be selected from any one or a combination of zinc oxide, titanium oxide, tantalum pentoxide, yttrium oxide, zirconium oxide, aluminum oxide, niobium oxide, tungsten oxide, antimony oxide, vanadium oxide and molybdenum oxide, but is not limited thereto.

In some embodiments, the light extraction layer 6 has a thickness of 0.5 to 10 μm, or 0.8 to 3 μm.

In some embodiments, the light extraction layer 6 has a flatness Ra of ≤20 nm, or ≤10 nm, or ≤5 nm. The flatness can ensure that the light extraction layer has a good reflection interface, thereby further reducing the adverse effect of ambient light on the contrast of the display panel.

In some embodiments, under illumination by light with a wavelength of 550 nm, the transmittance of the light extraction layer 6 is no more than 80%, alternatively no more than 75%, alternatively no more than 70%, alternatively no more than 65%, alternatively no more than 60%, alternatively no more than 55%, alternatively no more than 50%, alternatively no more than 45%, alternatively no more than 40%, alternatively no more than 35%, or alternatively no more than 30%. It can be observed that the appearance of the light extraction layer in the embodiment exhibits a certain degree of whiteness.

In some embodiments, the light extraction layer 6 may not include a polymer matrix; the nanoparticles are mixed with a solvent, and then the mixture is added into the sub-pixel regions; and after the solvent being volatilized, the light extraction layer can be formed. In some embodiments, some small molecular interface modifiers are used to modify the surface of the nanoparticles in advance, so as to increase the dispersibility of the nanoparticles in the solvent. When the nanoparticles and the solvent are mixed, the nanoparticles can be prevented from being agglomerated with each other, and after being applied to the sub-pixel regions, the light extraction layer will be relatively uniform due to the particle dispersion.

In other embodiments, the light extraction layer 6 can comprise a polymer matrix. The polymer matrix mainly plays the following roles: firstly, dispersing nanoparticles, and separating the nanoparticles by the polymer matrix so as to achieve stabilization; secondly, the nanoparticles are fixed so that they form as a whole; and thirdly, the polymer matrix can also have the function of filling gaps generated by nanoparticle stacking; when the content of the polymer matrix is further increased, the light extraction layer can be planarized, that is, the gaps are fully filled, and even all the nanoparticles can be covered by the excessive polymer matrix.

In some embodiments, the light extraction layer 6 includes at least one type of auxiliary material; under the irradiation of visible light, the light transmittance of the auxiliary material is not less than 80%, and preferably, the light transmittance is not less than 90%. The light transmittance refers to the transmittance of a film formed by using the auxiliary material alone of an actual light extraction ink formulation, for example, a solid content of the light extraction ink is 30 wt %, the auxiliary material accounts for 3 wt %, and the nanoparticles account for 27 wt %, the transmittance of the auxiliary material is approximately equal to the test value of the transmittance of the film formed by 3 wt % of the auxiliary material alone under visible light (400-1700 nm).

In some embodiments, the total mass fraction of the auxiliary material in the light extraction layer 6 is not more than 30 wt %, and the refractive index of each of the auxiliary materials is not less than 1.4. The auxiliary material can ensure that the overall refractive index of the entire light extraction layer is not relatively low. On the premise of ensuring that the overall refractive index of the light extraction layer meets the requirements, the greater the difference between the refractive index of the auxiliary material and the refractive index of the nanoparticles, the better, since the different refractive indexes of different materials is beneficial to improving the light extraction effect.

In some embodiments, the auxiliary material in the light extraction layer can be at least one of a binder, a viscosity modifier, an interface modifier, a rheological additive, etc. The binder may be selected from various curable resins; the viscosity modifier may be selected from various polymers such as PVK (poly(N-vinylcarbazole)) and the like; the interface modifier can be a silane coupling agent or a surfactant; and the rheological additive can be a levelling agent, a defoaming agent, etc. Any auxiliary material should meet the requirements of absorbing light as little as possible, having high transmittance, and being colorless and transparent.

In some embodiments, the auxiliary material includes an interface modifier that coordinates to the surface of the nanoparticles. The interface modifier can increase the dispersibility of the nanoparticles in the solvent. When the nanoparticles are mixed with the solvent, the nanoparticles can be prevented from being agglomerated with each other, so that after being applied to the sub-pixel regions, the light extraction layer will be relatively uniform.

In some embodiments, the light-emitting element further includes an interface layer 9 (e.g., a first interface layer). The interface layer 9 is disposed on a surface of the light extraction layer 6 away from the substrate 1. Under the irradiation of light with a wavelength of 550 nm, the transmittance of the interface layer is not less than 80%, the refractive index of the interface layer 9 is ≤1.8, and preferably, the refractive index of the interface layer 9 is no more than 1.5 and no less than 1. The material of the interface layer 9 can be selected from inorganic materials, and can be manufactured by a physical vapour deposition (sputtering, vapour deposition) or chemical vapour deposition (CVD) process; it may also be selected from organic materials, such as various types of resins; and may also be selected from organic-inorganic composite materials, such as a stacked structure of a layer of inorganic materials combined with a layer of organic materials, and may also be a thin film encapsulation, which can achieve the effect of blocking water and oxygen on the whole light-emitting element. In the above embodiments, the thickness of the interface layer 9 is 0.1 μm to 5 μm. The interface layer can improve the flatness of the light extraction layer, when the ambient light irradiates on the display panel, about half of the ambient light is firstly absorbed by the anti-reflection film (for example, the circular polarizer), The remaining half of the light, after exiting the anti-reflection film, reaches an interface of the interface layer away from the light extraction layer, most of the light is reflected by the interface and re-emitted to the anti-reflection film, and the phase of this part of the light just conforms to the absorption direction of the anti-reflection film, in this way, all ambient light is absorbed by the anti-reflection film, thereby further reducing adverse influence of ambient light on the contrast of the display panel; on the other hand, the interface layer can protect the light extraction layer.

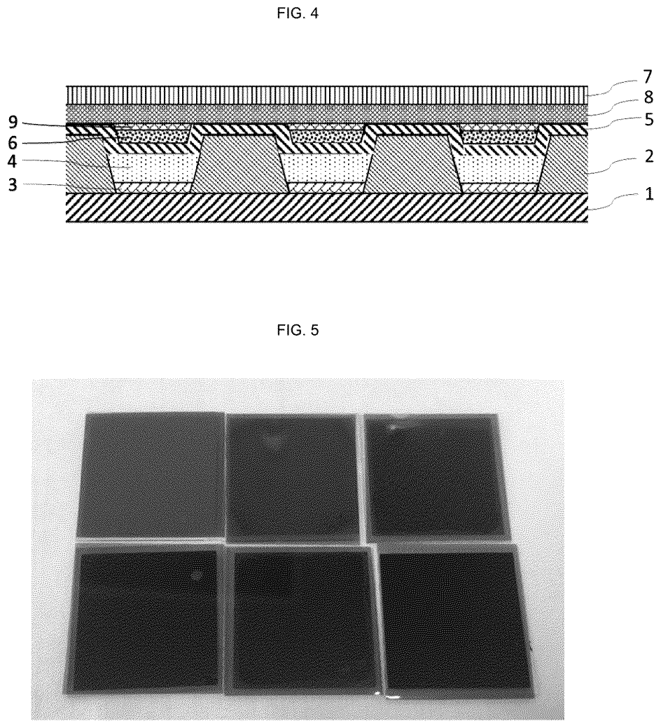

In some embodiments, the interface layer 9 is only disposed on the surface of the light extraction layer 6 in the light-emitting regions, as shown in FIG. 4.

In some embodiments, the interface layer 9 is disposed on the surface of the light extraction layer 6 and the exposed surface of the top electrode 5, as shown in FIG. 2.

In some embodiments, the light-emitting element further includes a second interface layer disposed between the top electrode and the light extraction layer. The second interface layer may protect the top electrode and the functional layer from physical or chemical damage to the light extraction material. The thickness of the second interface layer may be 40 to 300 nm. The material of the second interface layer may be selected from various metal oxides. In some embodiments, the above materials have a transmittance greater than 80% in the visible light region, and more preferably no less than 90%. For example, the material of the second interface layer may be selected from zinc oxide or zinc oxide doped with various metals, the doped metals may be one or more of Mg, Al and the like, it may also be selected from ITO, or molybdenum oxide or the like, or UV curable monomers and a mixture thereof, and the preparation of the second interface layer can be achieved by curing. In some embodiments, the refractive index of the second interface layer is not lower than that of the top electrode (or the functional layer next to the top electrode), so as to ensure that the light from the light-emitting layer can enter the light extraction layer smoothly.

In some embodiments, a sub-pixel with the highest initial external quantum efficiency in the original (when no light extraction layer is disposed) is defined as a first sub-pixel, a sub-pixel with the lowest initial external quantum efficiency is defined as a third sub-pixel, and a sub-pixel with an initial external quantum efficiency between the first sub-pixel and the third sub-pixel is defined as a second sub-pixel; the improvement ratio of the external quantum efficiency of the light extraction layer of the first sub-pixel is X₁, and the improvement ratio of the external quantum efficiency of the light extraction layer of the second sub-pixel is X₂, the improvement ratio of the external quantum efficiency of the light extraction layer of the third sub-pixel is X₃, The X₁, the X₂ and the X₃ are not equal, Xₙ=(Q₂−Q₁)/Q₁, wherein n is any natural number selected from 1 to 3, Q₁ is the original external quantum efficiency of the corresponding sub-pixel, Q₂ is the actual external quantum efficiency of the corresponding sub-pixel; the Xₙ≥0.5. The improvement ratio refers to the change of the external quantum efficiency caused only by the introduction of light extraction layer when the light-emitting element keeps other conditions unchanged. In some embodiments, the light-emitting element may be an RGB (red, green, blue) light-emitting device, and may also be an RGBW (red, green, blue, white) light-emitting device. Light extraction layers with different improvement ratios of efficiency are disposed for sub-pixels of different light-emitting colors, so that final external quantum efficiencies of the sub-pixels of different light-emitting colors are close, thereby synchronous aging and prolonging the lifetime of the display panel can be achieved.

In some embodiments, the display panel presents an all-black effect when the display panel is in a non-lighted state. In some embodiments, “all-black” means that, because the ambient light is completely absorbed after it enters the display panel, the entire display panel can be seen by naked eyes as black in a non-lighted state of the display panel, without a gray effect. In other embodiments, “all-black” also includes other all-black cases considered by those skilled in the art.

The beneficial effects of the present disclosure will be further described below in conjunction with specific examples and comparative examples.

For simplicity of experiments, the following examples are not prepared into a complete display panel, but those skilled in the art know how to form a complete display panel.

### EXAMPLE 1

### 1. Fabrication Process of Light-Emitting Element

A top-emitting pixelated substrate (the entire light-emitting area was 3*3 mm, and the light-emitting area was composed of a 80*80 μm sub-pixel groups and a bank for preventing light-mixing, the overall aperture ratio was about 52%), the reflective electrode was composed of Ag with a thickness of 100 nm and ITO with a thickness of 10 nm, and the hole injection layer HIL is PEDOT: PSS with a thickness of 40 nm, the hole transport layer HTL was a TFB with a thickness of 30 nm; the light-emitting layer EL was CdSe/ZnS red quantum dots with a thickness of 25 nm; the electron transport layer ETL was ZnO nanocrystals with a thickness of 50 nm, Each of the above layers was formed by an ink-jet printing process, and the film layer was obtained by vacuum, heating or the like, Under certain process conditions, an indium oxide/tin oxide (mass ratio of 9:1) mixed high-purity ITO target was vacuum-sputtered, and an ITO top electrode with a thickness of 80 nm was obtained.

### 2. Dispersion of the Nanoparticles (Namely, the Light Extraction Particles)

In a mixed solvent of ethanol and acetic acid in a volume ratio of 98:2, an appropriate amount of dodecyl trimethoxysilane was added and stirred until uniform; TiO₂ nanoparticles with a diameter of 40 nm as light extraction particles were added at a mass ratio of 10:1 based on the mass of the siloxane; after the mixture was kept stirring for one hour, the precipitate was removed by centrifuging; the mixture was washed with ethanol multiple times, subjected to centrifuging and dried properly; and the residue was dispersed in decane for storage.

### 3. Composition and Manufacturing Process of Light Extraction Ink

A self-made UV adhesive with a refractive index of 1.48 was diluted and dispersed with decane, then the siloxane-modified TiO₂ solution was added, and after fully mixing, the light extraction ink was obtained, wherein the total solid content of the UV adhesive and the nanoparticles was 15 wt %, wherein the nanoparticles accounted for 70% of the total mass of the UV adhesive and the nanoparticles, and the UV adhesive accounted for 30% of the total mass of the UV adhesive and the nanoparticles. in an inert atmosphere, the light extraction ink was disposed above the top electrode of the top-emitting pixelated substrate, a light extraction wet film with a certain thickness was obtained by means of step-by-step accelerating film formation using a spin coater, and after UV curing (while a solvent was removed) the light extraction layer was formed, so a light-emitting element was obtained. Then, a commercially available circular polarizer was directly bonded to the surface of the light extraction layer, and the photoelectric performance was tested (under an inert atmosphere).

### 4 Test Method

(1) Transmittance of the light extraction layer: film formation was performed on a transparent mother glass by using the same formulation and the same film formation process, and the transmittance of the light extraction layer is obtained by using an ultraviolet-visible spectrophotometer with the mother glass as a reference after the background of the transparent glass was deducted.

(2) Roughness of the light extraction layer: Ra value was obtained by measuring roughness of the surface of the light extraction layer with an atomic force microscope AFM.

(3) External quantum efficiency: a Keithley 2400 power source was used to provide voltage input for the light-emitting element and obtain a corresponding current output; and an integrating sphere (FOIS-1) combined with an optical spectrometer (QE-pro, Ocean optics) was used to measure the luminance of the light-emitting element (the test object was the light-emitting element with the circular polarizer). The test results were recorded in Table 2. The external quantum efficiency of the light-emitting element was obtained according to parameters such as the measured current density and luminance. The higher the external quantum efficiency is, the better the performance of the light-emitting element is, and the lifetime of the light-emitting element can also be improved correspondingly.

(4) Lifetime: taking 1000 nit as a starting point (i.e., initial luminance) of the luminance test, making the input current of the light-emitting element constant, a luminance change of the light-emitting element was recorded in real time, and a time value after luminance of the light-emitting element decays to 95% of the initial value (1000 nit*0.95=950 nit) is defined as T95, i.e., the lifetime test was stopped after the luminance of the light-emitting element decays to 950 nit. The test results were recorded in Table 2. It should be noted that the test object here is a light-emitting element with the circular polarizer. Since the commercially available circular polarizer has nearly 50% loss to the light emitted by the light-emitting element, the initial brightness read by the instrument was 1000 nit, but the initial brightness of the light-emitting element itself was about 2000 nit, i.e., the lifetime of the light-emitting element was obtained by testing under the condition that the initial luminance was about 2000 nit.

### EXAMPLES 2 TO 6, 8

The same fabrication process as that in Example 1 was used, and the specific parameters were shown in Table 1.

### EXAMPLE 7

The difference between this example and Example 1 lies in that: an interface layer was further disposed on a surface of the light extraction layer away from the top-emitting pixelated substrate, and a polystyrene (PS) interface layer with a thickness of 4.2 μm was obtained by an inkjet printing device.

### Comparative Example 1

The difference between this example and Example 1 lies in that the light extraction layer was not disposed.

### Comparative Example 2

The difference between this example and Example 1 lies in that the diameter of the light extraction particles was 300 nm.

TABLE 1

| | Type of light | | | | Transmittance | Flatness | | Refractive | Refractive |
|---|---|---|---|---|---|---|---|---|---|
| | extraction | Diameter | | | and thickness | (Ra) of | | index | index |
| | particles | of light | | | of light | light | | of light | of light |
| | and its mass | extraction | | Auxiliary material | extraction | extraction | | extraction | extraction |
| No. | fraction | particles | | (mass fraction) | layer | layer | | particles | layer |
| Example 1 | TiO₂, 70% | 40 | nm | Dodecyl | 79%, 800 nm | 11 | nm | 2.65 | 1.882 |
| | | | | trimethoxysilane(7%), | | | | | |
| | | | | UV adhesive(23%) | | | | | |
| Example 2 | TiO₂, 50% | 40 | nm | Dodecyl | 85%, 800 nm | 7.1 | nm | 2.65 | 1.864 |
| | | | | trimethoxysilane(5%), | | | | | |
| | | | | UV adhesive(45%, | | | | | |
| | | | | n = 1.71) | | | | | |
| Example 3 | MoO₃, 90% | 10 | nm | Triethoxy(oc- | 63%, 2000 nm | 5.6 | nm | 2.16 | 1.885 |
| | | | | tyl)silane (10%) | | | | | |
| Example 4 | ZnO, 80% | 20 | nm | Solsperse38500(12%), | 37%, 2350 nm | 9.7 | nm | 2.02 | 1.709 |
| | | | | UV adhesive(8%) | | | | | |
| Example 5 | ZnO, 85% | 5 | nm | 4-Amino-2-butanol (5%), | 45%, 3500 nm | 4.1 | nm | 2.02 | 1.75 |
| | | | | Solsperse40000(10%) | | | | | |
| Example 6 | TiO₂, 70% | 15 | nm | Dodecyl | 23%, 2650 nm | 5.1 | nm | 2.65 | 1.975 |
| | | | | trimethoxysilane(7%), | | | | | |
| | | | | PVK(18%), | | | | | |
| | | | | UVadhesive(5%) | | | | | |
| Example 7 | TiO₂, 70% | 40 | nm | Dodecyl | 81%, 800 nm | 4.5 | nm | 2.65 | 1.882 |
| | | | | trimethoxysilane(7%), | | | | | |
| | | | | UV adhesive(23%) | | | | | |
| Example 8 | ZrO₂, 70% | 10 | nm | Dodecyl | 71%, 1500 nm | 3.2 | nm | 2.17 | 1.662 |
| | | | | trimethoxysilane(7%), | | | | | |
| | | | | UV adhesive(23%) | | | | | |
| Comparative | \ | \ | | \ | \ | \ | | \ | \ |
| Example 1 | | | | | | | | | |
| Comparative | TiO₂, 70% | 300 | nm | Dodecyl | 35%, 800 nm | 21 | nm | 2.65 | 1.882 |
| Example 2 | | | | trimethoxysilane(7%), | | | | | |
| | | | | UV adhesive(23%) | | | | | |

Reference values for refractive index n (@550 nm) of the related substances listed in Table 1: UV adhesive of Example 1, 4, 6, 7, 8 and Comparative example 2 was 1.48, UV adhesive of example 2 was 1.71; ZrO₂ was 2.17; TiO₂ was 2.65; ZnO was 2.02; MoO₃ was 2.16; the silane coupling agent was about 1.42; the Solsperse® series was a polymer dispersing agent with a refractive index of about 1.48; 4-amino-2-butanol was about 1.45; and PVK was about 1.68. The mass fraction in the “Type of light extraction particles and its mass fraction” in Table 1 refers to the proportion of the light extraction particles in the total solid content, i.e., the mass percentage of the light extraction particles in the cured light extraction layer. The flatness (Ra) of light extraction layer of Example 7 was actually tested with the surface roughness of the PS interface layer.

TABLE 2

| | No. | | | | |
|---|---|---|---|---|---|
| | Example 1 | Example 2 | Example 3 | Example 4 | Example 5 |
| External | 7.3% | 7.2% | 8.9% | 7.9% | 8.7% |
| quantum | | | | | |
| efficiency | | | | | |
| T95 lifetime | 81 h | 79 h | 113 h | 92.7 h | 104.9 h |

| | No. | | | | |
|---|---|---|---|---|---|
| | | | | Comparative | Comparative |
| | Example 6 | Example 7 | Example 8 | Example 1 | Example 2 |
| External | 9.9% | 7.5% | 6.7% | 5.2% | 9.3% |
| quantum | | | | | |
| efficiency | | | | | |
| T95 lifetime | 149 h | 89.6 h | 73.5 h | 50.1 h | 145.2 h |

It can be seen obviously from FIG. 5 that although the light-emitting element of Comparative Example 2 using large-size (300 nm) particles as light extraction particles has a good light extraction effect (namely, the improvement of external quantum efficiency was significant), after the circular polarizer was adhered, an all-black effect was severely destroyed, and the whole appeared gray, thereby greatly affecting the display contrast. In each of the light extraction layers in Examples 1, 2, 6, 7, and 8. As shown in FIG. 5, nanoparticles having a diameter of not more than 40 nm were used as the light extraction particles, and as the surface flatness Ra value of the light extraction layer decreased, the effect of all-black became more remarkable.

It should be noted that, in the actual product structure of the display panel, the light-emitting element can further include an encapsulation layer, After the stacked layers of the thin film encapsulation was disposed on the surface of the light extraction layer, the overall Ra value of the film layer will be further reduced, That was, the overall smoothness of the film layer will be further improved, and then after the circular polarizer was adhered, the all-black effect of the display panel will be better, Therefore, in order to show that the beneficial effects of the present disclosure indeed come from the improvement of the light extraction layer, in the above examples and comparative examples, the light-emitting element (or the light-emitting element with the circular polarizer) was selected as the object of the photovoltaic performance test. It can be seen that the display panel using the light-emitting element of the present disclosure has a good display contrast, and can present the all-black effect in a non-lighted state.

In conjunction with Table 1 and Table 2, it can be seen that, in Examples 1 to 7, when the refractive index of the light extraction layer was not lower than that of the top electrode (the refractive index of ITO was 1.8), in the above thickness range of the light extraction layer, the improvement ratio of the external quantum efficiency of the light-emitting element (the improvement ratio was calculated compared with Comparative Example 1) was in direct proportion to the increase of the thickness of the light extraction layer, and accordingly, the lifetime of the light-emitting element was also steadily increased. In Example 8, although the thickness of the light extraction layer was also relatively suitable, the refractive index of the light extraction layer was relatively low, so that the improvement ratio of the external quantum efficiency of the light-emitting element (the improvement ratio was calculated as compared with Comparative Example 1) was lower than that in other examples. It is worth mentioning that, in Example 2, small-particle-size nanoparticles are still used as light extraction particles, and the mass fraction of the nanoparticles was appropriately reduced; and the UV adhesive with a high refractive index was used, so that the overall refractive index of the light extraction layer was still higher than that of the top electrode, and a better light extraction effect was also achieved.

The foregoing are only preferred embodiments of the present disclosure and are not intended to limit the present disclosure. For those skilled in the art, the present disclosure may have various modifications and variations. Any modifications, equivalent replacements, improvements and the like made within the spirit and principle of the present disclosure shall belong to the scope of protection of the present disclosure.

1. A display panel, characterized in that, comprising an anti-reflection film and a light-emitting element, wherein the light-emitting element comprises a substrate and a plurality of mutually isolated sub-pixels disposed on a surface of the substrate, each of the sub-pixels comprises a bottom electrode, a functional layer and a top electrode which are sequentially stacked, and at least part of the sub-pixels further comprise a light extraction layer, the light extraction layer is disposed on a surface of the top electrode away from the functional layer, and nanoparticles are disposed in the light extraction layer, a diameter of the nanoparticles does not exceed 40 nm.

2. The display panel according to claim 1, characterized in that, a mass fraction of the nanoparticles in the light extraction layer is ≥70 wt %.

3. The display panel according to claim 1, characterized in that, a mass fraction of the nanoparticles in the light extraction layer is greater than or equal to 50 wt %, and the light extraction layer comprises a polymer matrix having a refractive index greater than 1.65.

4. The display panel according to claim 1, characterized in that, the nanoparticles have a diameter of 5 to 30 nm.

5. The display panel according to claim 1, characterized in that, the nanoparticles have a refractive index of ≥1.8.

6. The display panel according to claim 1, characterized in that, the surface of said nanoparticles is a curved surface.

7. The display panel according to claim 6, characterized in that, the nanoparticles are selected from any one or a combination of zinc oxide, titanium oxide, tantalum pentoxide, yttrium oxide, zirconium oxide, aluminum oxide, niobium oxide, tungsten oxide, antimony oxide, vanadium oxide and molybdenum oxide.

8. The display panel according to claim 1, characterized in that, the light extraction layer has a thickness of 0.5 to 10 μm.

9. The display panel according to claim 1, characterized in that, the light extraction layer has a roughness Ra of ≤20 nm.

10. The display panel according to claim 1, characterized in that, under the irradiation of light with a wavelength of 550 nm, a transmittance of the light extraction layer is no more than 80%.

11. The display panel according to claim 1, characterized in that, the light extraction layer comprises at least one type of auxiliary material, and under the irradiation of visible light, a light transmittance of the auxiliary material is not less than 80%.

12. The display panel according to claim 11, characterized in that, the total mass fraction of the auxiliary material in the light extraction layer is not more than 30 wt %, and the refractive index of each auxiliary material is not less than 1.4.

13. The display panel according to claim 12, characterized in that, the auxiliary material comprises an interface modifier, the interface modifier is coordinated to the surface of the nanoparticles.

14. The display panel according to claim 1, characterized in that, the light-emitting element further comprises an interface layer, wherein the interface layer is disposed on a surface of the light extraction layer away from the substrate, a transmittance of the interface layer is not less than 80% under the irradiation of light with a wavelength of 550 nm, and the refractive index of the interface layer is ≤1.8.

15. The display panel according to claim 14, characterized in that, a thickness of the interface layer is 0.1 to 5 μm.

16. The display panel according to claim 1, characterized in that, defining the sub-pixel with the highest initial external quantum efficiency as a first sub-pixel, the sub-pixel with the lowest initial external quantum efficiency as a third sub-pixel, and the sub-pixel with the initial external quantum efficiency between the first sub-pixel and the third sub-pixel as a second sub-pixel; the improvement ratio of the external quantum efficiency of the light extraction layer of the first sub-pixel is X₁, and improvement ratio of the external quantum efficiency of the light extraction layer of the second sub-pixel is X₂, the improvement ratio of the external quantum efficiency of the light extraction layer of the third sub-pixel is X₃, and the X₁, the X₂ and the X₃ are not equal, defining Xₙ=(Q₂−Q₁)/Q₁, in which n is a natural number selected from 1 to 3, Q₁ is the initial external quantum efficiency of the corresponding sub-pixel, Q₂ is the actual external quantum efficiency of the corresponding sub-pixel; the Xₙ is ≥0.5.

17. The display panel according to claim 1, characterized in that, in a non-lighted state of the display panel, the display panel presents an all-black effect.

18. The display panel according to claim 2, characterized in that, the light extraction layer has a roughness Ra of ≤20 nm.

19. The display panel according to claim 2, characterized in that, the light extraction layer comprises at least one type of auxiliary material, and under the irradiation of visible light, a light transmittance of the auxiliary material is not less than 80%.

20. The display panel according to claim 2, characterized in that, the light-emitting element further comprises an interface layer, wherein the interface layer is disposed on a surface of the light extraction layer away from the substrate, a transmittance of the interface layer is not less than 80% under the irradiation of light with a wavelength of 550 nm, and the refractive index of the interface layer is ≤1.8.
